(19) United States
(12) Patent Application Publication
(10) Pub. No.: US 2025/0212555 A1
(43) Pub. Date: Jun. 26, 2025

(54) STAMP FOR TRANSFERRING LED, METHOD FOR TRANSFERRING LED USING THE SAME, AND DISPLAY DEVICE

(71) Applicant: LG Display Co., Ltd., Seoul (KR)

(72) Inventors: Woo Sung KIM, Paju-si (KR); Yong Hoon LEE, Paju-si (KR); Jong Soo HAN, Paju-si (KR); Sang Hak SHIN, Paju-si (KR); Hyoung Sun PARK, Paju-si (KR); Hyun Seok NA, Paju-si (KR); Hyun Chyol SHIN, Paju-si (KR); Seong Soo CHO, Paju-si (KR); Kyeong Min YUK, Paju-si (KR); Joon Min JANG, Paju-si (KR); Seung Kyu IM, Paju-si (KR); Bong Soo JEON, Paju-si (KR)

(73) Assignee: LG Display Co., Ltd., Seoul (KR)

(21) Appl. No.: 18/953,846

(22) Filed: Nov. 20, 2024

(30) Foreign Application Priority Data
Dec. 21, 2023 (KR) 10-2023-0188362

(51) Int. Cl. H01L 33/00; H01L 25/075

(52) U.S. Cl. CPC H10H 20/01; H01L 25/0753

(57) ABSTRACT

A stamp for transferring light-emitting elements, a method for transferring the light-emitting elements using the stamp, and a display device including the light-emitting elements are discussed. The stamp can include a stamp substrate, a non-overlapping stamp pattern area defined on the stamp substrate, an overlapping stamp pattern area adjoining an outer periphery of the non-overlapping stamp pattern area, a plurality of first pickup transfer patterns disposed in the non-overlapping stamp pattern area, and a plurality of second pickup transfer patterns disposed in different lines in the overlapping stamp pattern area with the non-overlapping stamp pattern area interposed therebetween.

### CROSS-REFERENCE TO RELATED APPLICATION

This application claims priority to Korean Patent Application No. 10-2023-0188362, filed in the Republic of Korea on Dec. 21, 2023, the disclosure of which is hereby expressly incorporated by reference in its entirety into the present application.

### BACKGROUND

### Field

The present disclosure relates to a display device, and more particularly to a stamp for transferring light-emitting elements (LED), a method for transferring the light-emitting elements using the stamp, and a display device.

### Discussion of the Related Art

Advances in technology have led to the development of display devices that incorporate spontaneous emission elements. The display devices incorporating the spontaneous emission elements can be an organic light-emitting display device including an organic material as an emission layer and a micro-LED display device using micro light-emitting elements.

A micro light-emitting element is an extremely small light-emitting element with a size of tens of μm or less. The use of such micro light-emitting elements as pixels makes it possible to miniaturize and reduce the weight of devices. However, the light-emitting elements are very small in size and a large number of light-emitting elements need to be formed, which is expensive and time-consuming to manufacture.

### SUMMARY OF THE DISCLOSURE

In order to manufacture a display device incorporating micro light-emitting elements, the micro light-emitting elements can be crystallized on a substrate such as sapphire or silicon, and then the crystallized micro light-emitting elements can be transferred to a substrate having driving circuits. In a process of transferring the micro light-emitting elements, a method of stamping a plurality of micro light-emitting elements which have been picked up on a stamp can be used to stamp the plurality of micro light-emitting elements on a panel substrate on which the driving circuits are formed.

However, since there is a difference in the transfer process capability for each transfer area of the stamp, a stamp smear can occur on the stamp boundary portion or the stamp surface.

Therefore, the stamp smear which can be caused by transferring the plurality of micro light-emitting elements several times on the substrate using the stamp can be visible, which can increase a defect rate of the micro-light-emitting elements and thus can reduce the yield of the display device.

In order to solve the above problems and other issues associated with the related art, an object of the present disclosure is to provide a stamp for transferring light-emitting elements, a method for transferring light-emitting elements using the stamp, and a display device that are capable of improving the visibility of stamp smears in the panel to reduce a defect rate of micro-LED transfer using the stamp, thereby improving the yield.

The problems to be solved by the present disclosure are not limited to those mentioned above, and other problems not mentioned will be clearly understood by those skilled in the art from the following description.

A stamp for transferring light-emitting elements according to one or more embodiments of the present disclosure include a stamp substrate; a non-overlapping stamp pattern area defined on the stamp substrate, and an overlapping stamp pattern area adjoining an outer periphery of the non-overlapping stamp pattern area; a plurality of first pickup transfer patterns disposed in the non-overlapping stamp pattern area; and a plurality of second pickup transfer patterns disposed in different lines in the overlapping stamp pattern area with the non-overlapping stamp pattern area interposed therebetween.

According to some embodiments of the present disclosure, a method for transferring light-emitting elements using a stamp, which includes: preparing a substrate having a plurality of transfer areas divided into non-overlapping and overlapping transfer areas; preparing a stamp, the stamp including a plurality of first pickup transfer patterns configured to transfer a plurality of first light-emitting elements to the non-overlapping transfer areas of the substrate, and a plurality of second pickup transfer patterns configured to transfer a plurality of second light-emitting elements to the overlapping transfer areas of the substrate; and transferring the plurality of first light-emitting elements picked up onto the plurality of first pickup transfer patterns to the non-overlapping transfer areas of the substrate and transferring the plurality of second light-emitting elements picked up onto the plurality of second pickup transfer patterns to the overlapping transfer areas, by performing a plurality of transfer processes using the stamp.

According to some embodiments of the present disclosure, a display device includes: a substrate having a plurality of transfer areas; a substrate having a plurality of transfer areas; non-overlapping and overlapping transfer areas defined in each of the plurality of transfer areas; a plurality of bank patterns disposed in the non-overlapping transfer areas and the overlapping transfer areas of the substrate; a plurality of first electrodes disposed on the plurality of bank patterns; a plurality of light-emitting elements disposed on the plurality of first electrodes; and a second electrode disposed on the plurality of light-emitting elements, wherein the light-emitting elements disposed in the overlapping transfer areas include light-emitting elements that overlap with the bank pattern to each other on the first electrode and light-emitting elements having a portion which does not overlap with the bank pattern on the first electrode.

According to some aspects of the present disclosure, the visibility of stamp smears can be improved by defining an overlapping transfer area in a plurality of transfer areas defined on a substrate and by offsetting differences in process capabilities between the stamp transfer processes in the overlapping transfer area when transferring a plurality of light-emitting elements using a stamp.

According to some aspects of the present disclosure, when transferring a plurality of light-emitting elements using a stamp, the difference in the process capability between the stamp transfer processes in the overlapping transfer area can be minimized to reduce the stamping smear defect rate during panel image inspection, such as AP inspection and module inspection, thereby improving the yield of the manufacturing process.

The effects of the present disclosure are not limited to the above-mentioned effects, and other effects that are not mentioned will be apparently understood by those skilled in the art from the following description and the appended claims.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a diagram illustrating a display device according to one or more embodiments of the present disclosure;

FIG. 2 is an enlarged view of an area A in FIG. 1;

FIG. 3 is a diagram illustrating a partial area of a pixel according to some embodiments of the present disclosure;

FIG. 4 is a cross-sectional view taken along line I-I′ in FIG. 3;

FIG. 5 is a cross-sectional view taken along line II-II′ in FIG. 3;

FIG. 6 is an enlarged view of an area B in FIG. 5;

FIGS. 7A and 7B are perspective views illustrating a process for picking up and transferring light-emitting elements using a light-emitting element transfer stamp according to one embodiment of the present disclosure;

FIGS. 8A and 8B are perspective views illustrating a first and second transfer process using a light-emitting element transfer stamp according to one embodiment of the present disclosure;

FIG. 9 is a plan view illustrating a light-emitting element transfer stamp according to one embodiment of the present disclosure;

FIG. 10 is a cross-sectional view taken along line III-III′ in FIG. 9;

FIG. 11 is a plan view illustrating a substrate on which transfer areas are defined according to one embodiment of the present disclosure;

FIG. 12 is an enlarged view of an area C in FIG. 11;

FIG. 13 is a cross sectional view taken along line IV-IV in FIG. 11;

FIG. 14 is a cross-sectional view taken along line V-V′ in FIG. 13;

FIG. 15 is a cross-sectional view taken along line VI-VI′ in FIG. 13; and

FIGS. 16A and 16B are diagrams illustrating whether or not stamp smears are visible when the overlapping transfer area is employed and not employed during a process of transferring a plurality of light-emitting elements using a stamp according to one embodiment of the present disclosure.

### DETAILED DESCRIPTION OF THE EMBODIMENTS

The advantages and features of the present disclosure, and methods of achieving them will become apparent upon reference to the embodiments described in detail below in conjunction with the accompanying drawings. However, the present specification is not limited to the following embodiments, but can be implemented in various different forms; rather, the present embodiments are provided to make the disclosure of the present specification complete and to enable those skilled in the art to fully understand the scope of the present specification, and the present specification is defined within the scope of the appended claims.

The shapes, sizes, proportions, angles, numbers, and the like of elements shown in the drawings to illustrate embodiments of the present disclosure are merely illustrative and are not intended to be limiting. Further, in describing the present disclosure, detailed descriptions of well-known technologies can be omitted so as not to obscure the essence of the present disclosure.

The terms such as “comprising,” “having,” and “consisting of” used herein are generally intended to allow for the addition of other components unless the terms are used with the term “only.” References to components of a singular noun include the plural of that noun, unless specifically stated otherwise.

In interpreting components, they are construed to include a margin of error, even if it is not explicitly stated.

When describing the positional relationship, for example, if the positional relationship of the two parts is described as “on,” “above,” “below,” and “next to,” one or more other parts can be located between the two parts unless “immediately” or “directly” is used.

When an element or layer is referred to as being on another element or layer, this includes any intervening layer or other element directly on top of or in between the other element.

In addition, first, second, etc., are used to describe various components, but these components are not limited by these terms. These terms are used only to distinguish one component from another. Therefore, the first component referred to below can be a second component within the technical spirit of the present disclosure.

Identical reference numerals can designate identical components throughout the description.

The sizes and thicknesses of each configuration shown in the drawings are shown for illustrative purposes only and are not necessarily limited to the sizes and thicknesses of the configurations shown herein.

Each of the features of various embodiments described herein can be coupled or combined with one another in whole or in part, and can be technologically interlocked and operated in various ways, and each of the embodiments can be carried out independently or in conjunction with one another.

Hereinafter, various embodiments of the present disclosure will be described in detail with reference to the accompanying drawings.

A display device according to one or more embodiments of the present disclosure includes a display panel having a display area or screen on which an image is displayed, and a pixel driving circuit that drives pixels of the display panel. The display area includes a pixel area in which the pixels are arranged. The pixel area includes a plurality of light-emitting areas. A light-emitting element is disposed in each of the light-emitting areas. The pixel driving circuit can be embedded in the display panel. Further, an LED can be a light-emitting element or a light emitting diode or the like.

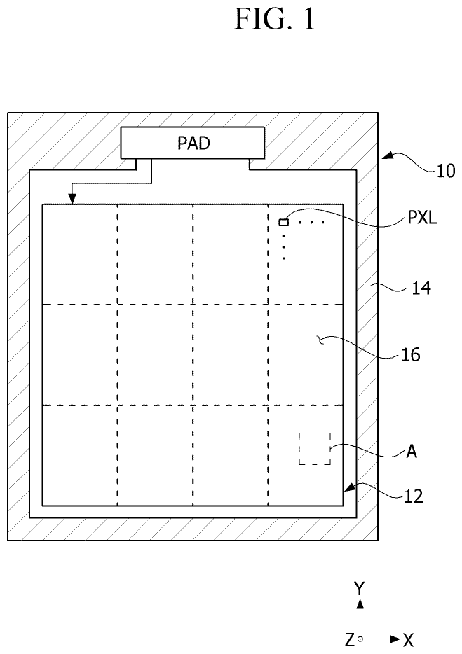

FIG. 1 is a diagram illustrating a display device according to one or more embodiments of the present disclosure.

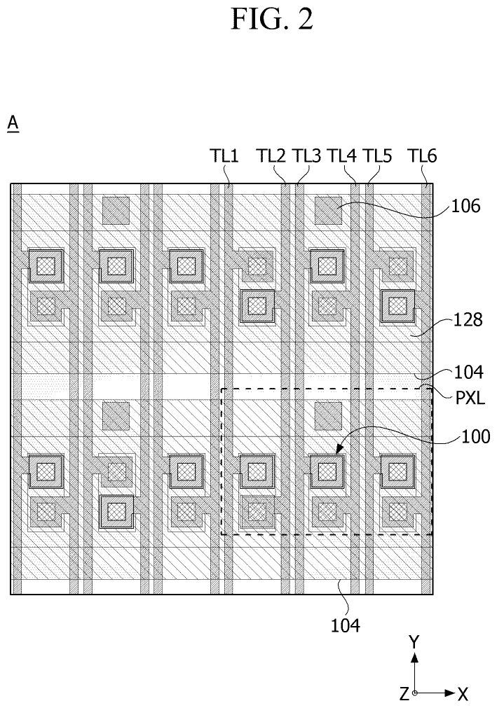

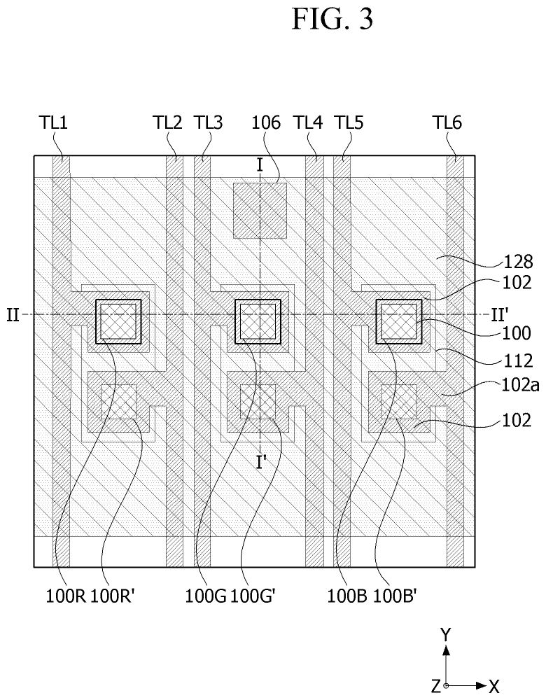

FIG. 2 is an enlarged view of an area A in FIG. 1. FIG. 3 is a diagram illustrating a partial area of a pixel according to some embodiments of the present disclosure.

Referring to FIGS. 1 and 2, a display device 10 according to an embodiment of the present disclosure includes a display panel on which an input image is visually reproduced. The display panel can include a display area 12 in which the image is displayed and a non-display area 14 in which no image is displayed. In the non-display area 14, various wires and driving circuits can be mounted and a pad portion PAD can be disposed to which integrated circuits, printed circuits, etc. are connected. The non-display area 14 can surround the display area 12 entirely or only in part(s).

A plurality of light-emitting elements 100 disposed in the display area 12 to form the pixels PXL can be micro-sized inorganic light-emitting elements. The inorganic light-emitting elements can be grown on a silicon wafer and then attached to the display panel through a transfer process.

The transfer process of the light-emitting element 100 can be performed for each pre-divided area. Although FIG. 1 illustrates that the display area 12 is divided into twelve transfer areas 16, the size of the transfer area or the number of divisions of the transfer areas is not limited thereto. The transfer process can be sequentially or simultaneously performed in a first transfer region 16 to a twelfth transfer region 16. A blue light-emitting element 100, a green light-emitting element 100, and a red light-emitting element 100 can be sequentially transferred to the transfer region 16.

In the non-display area 14, a data driving circuit or a gate driving circuit can be disposed and wires for supplying a control signal for controlling the driving circuits can be disposed. Here, the control signal can include various timing signals including a clock signal, an input data enable signal, and synchronization signals, and can be received through the pad portion PAD.

The pixels PXL can be driven by the pixel driving circuit. The pixel driving circuit can receive a driving voltage, an image signal (digital signal), a synchronization signal synchronized with the image signal, and the like, and can output an anode voltage and a cathode voltage of the light-emitting element 100 to drive the plurality of pixels. The driving voltage can be a high potential voltage EVDD. The cathode voltage can be a low potential voltage EVSS commonly applied to the pixels. The anode voltage can be a voltage corresponding to a pixel data value of the image signal. The pixel driving circuit can be disposed in the non-display area 14, or can be disposed below the display area 12.

Each of the pixels PXL can include a plurality of sub-pixels having different colors. For example, the plurality of pixels can include a red sub-pixel in which the light-emitting element 100 that emits light of a red wavelength is disposed, a green sub-pixel in which the light-emitting element 100 that emits light of a green wavelength is disposed, and a blue sub-pixel in which the light-emitting element 100 that emits light of a blue wavelength is disposed. The plurality of pixels can further include a white sub-pixel.

Referring to FIGS. 2 and 3, the plurality of pixels PXL can be successively arranged in the first direction (the X-axis direction) and the second direction (the Y-axis direction). A plurality of sub-pixels of the same color can be disposed within the pixel of the display area 12. For example, each of the plurality of sub-pixels can include a first red sub-pixel in which a first-first red light-emitting element 100R that emits light of a red wavelength is disposed, a second red sub-pixel in which a first-second red light-emitting element 100R′ that emits light of a red wavelength is disposed, a first green sub-pixel in which a second-first green light-emitting element 100G that emits light of a green wavelength is disposed, a second green sub-pixel in which a second-second green light-emitting element 100G′ that emits light of a green wavelength is disposed, a first blue sub-pixel in which a third-first blue light-emitting element 100B that emits light of a blue wavelength is disposed, and a second blue sub-pixel in which a third-second blue light-emitting element 100B′ that emits light of a blue wavelength is disposed. The first-first red light-emitting element 100R, the second-first green light-emitting element 100G, and the third-first blue light-emitting element 100B can be regarded as main light-emitting elements. The first-second red light-emitting element 100R′, the second-second green light-emitting element 100G′, and the third-second blue light-emitting element 100B′ can be regarded as sub-light-emitting elements.

One sub-pixel can include at least one or more light-emitting elements, and in the event that one light-emitting element becomes defective, the luminance of another light-emitting element can be increased to adjust the luminance of the sub-pixel. However, the embodiment is not necessarily limited thereto, and one sub-pixel can include only one light-emitting element.

A plurality of first electrodes 102 can be disposed on the lower portion of the light-emitting element 100, respectively, and can be selectively connected to a plurality of signal wires TL1 to TL6 by an extension portion 102a. The high potential voltage can be applied to the pixel driving circuit through the signal wires TL1 to TL6. The signal wires TL1 to TL6 and the first electrodes 102 can be formed as integrated electrode patterns during the electrode patterning process.

For example, a first signal wire TL1 can be connected to an anode electrode of the first red sub-pixel, and a second signal wire TL2 can be connected to an anode electrode of the second red sub-pixel. A third signal wire TL3 can be connected to an anode electrode of the first green sub-pixel, and a fourth signal wire TL4 can be connected to an anode electrode of the second green sub-pixel. A fifth signal wire TL5 can be connected to an anode electrode of the first blue sub-pixel, and a sixth signal wire TL6 can be connected to an anode electrode of the second blue sub-pixel. When one sub-pixel includes only one light-emitting element, the number of the signal wires TL can be reduced by half.

A second electrode 104 can be a cathode electrode that is disposed one for each row and applies a cathode voltage to the light-emitting elements 100 arranged successively in the first direction (the X-axis direction). A plurality of second electrodes 104 can be spaced apart from each other in the second direction (the Y-axis direction). The plurality of second electrodes 104 can be connected to the cathode voltage through a contact electrode 106. Each of the plurality of second electrodes 104 can be electrically connected to the contact electrode 106. However, the embodiment is not necessarily limited thereto, and the second electrode 104 can be configured as one electrode layer without being divided into a plurality of electrodes and can function as a common electrode.

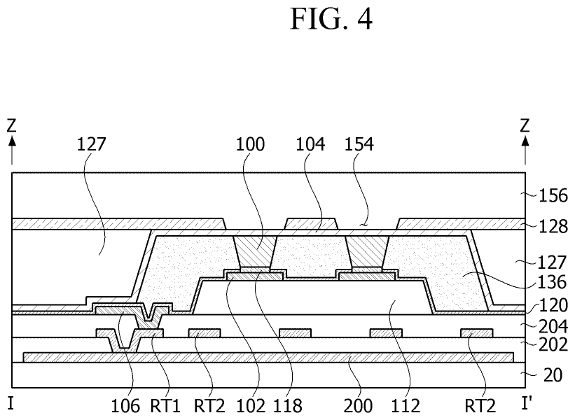

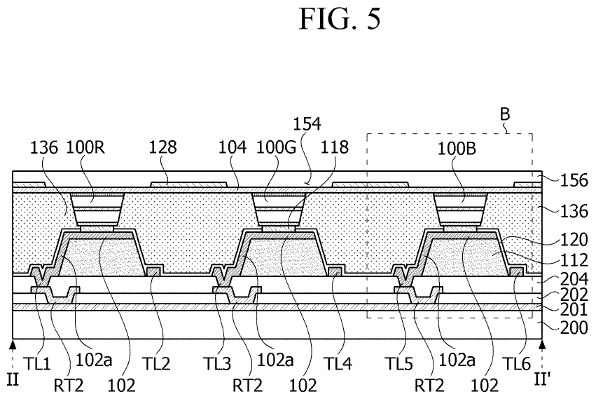

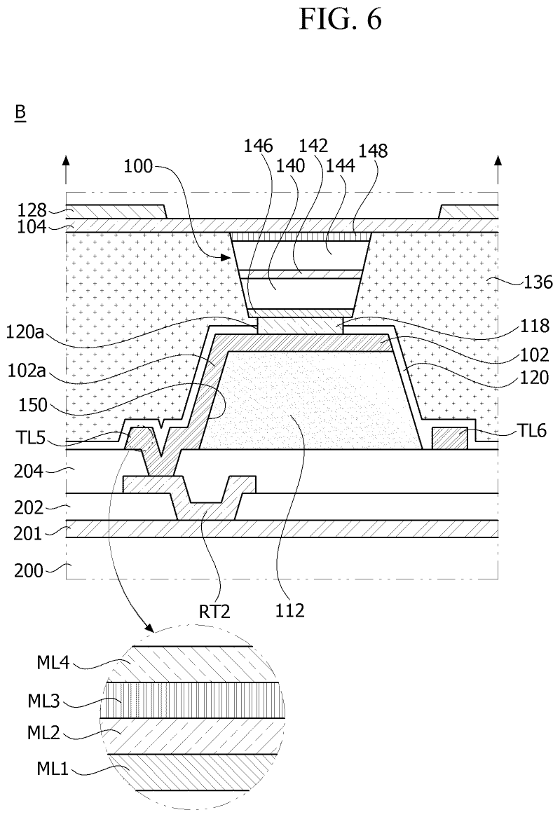

FIG. 4 is a cross-sectional view taken along line I-I′ in FIG. 3. FIG. 5 is a cross-sectional view taken along line II-II′ in FIG. 3. FIG. 6 is an enlarged view of an area B in FIG. 5.

Referring to FIGS. 4 to 6, the display device according to an embodiment of the present disclosure includes the plurality of first electrodes 102 and the contact electrode 106 disposed above a substrate 200, the plurality of light-emitting elements 100 disposed on the plurality of first electrodes 102, and a first optical layer 136 disposed between the plurality of light-emitting elements 100. It further includes a second electrode 104 disposed on the first optical layer 136.

The substrate 200 can be made of plastic having flexibility. For example, the substrate 200 can be fabricated as a single layer substrate or a multi-layer substrate of materials selected from, but not limited to, polyimide, polyethylene terephthalate, polyethylene naphthalate, polycarbonate, polyethersulfone, polyarylate, polysulfone, and cyclic olefin copolymer. For example, the substrate 20 can be a ceramic substrate or a glass substrate.

A pixel driving circuit 201 can be disposed in the display area 12 on the substrate 200. The pixel driving circuit 201 can include a plurality of thin film transistors using an amorphous silicon semiconductor, a polycrystalline silicon semiconductor, or an oxide semiconductor.

The pixel driving circuit 201 can include at least one driving thin film transistor, at least one switching thin film transistor, and at least one storage capacitor. When the pixel driving circuit 201 includes the plurality of thin film transistors, it can be formed on the substrate 200 by a thin film transistor (TFT) manufacturing process. In an embodiment, the pixel driving circuit 201 can be a collective term for the plurality of thin film transistors electrically connected to the light-emitting element 100.

The pixel driving circuit 201 can be a driver manufactured using a metal-oxide-silicon field effect transistor (MOSFET) manufacturing process on the single crystal semiconductor substrate 200. The driver can include the plurality of pixel driving circuits to drive the plurality of sub-pixels. When the pixel driving circuit 201 is implemented as the driver, an adhesive layer can be disposed on the substrate 200 and then the driver can be mounted on the adhesive layer by a transfer process.

A buffer layer 202 covering the pixel driving circuit 201 can be disposed on the substrate 200. The buffer layer 202 can be made of an organic insulating material, e.g., photosensitive photo acryl or photosensitive polyimide, but is not limited thereto.

An insulating layer 204 can be disposed on the buffer layer 202. The insulating layer 204 can be made of an organic insulating material, e.g., photosensitive photo acryl or photosensitive polyimide, but is not limited thereto. Connection wires RT1 and RT2 can be disposed on the buffer layer 202. The connection wires RT1 and RT2 can be connected as the corresponding signal wires TL1 to TL6 or can be connected to the signal wires TL1 to TL6. The connection wires RT1 and RT2 can include a plurality of wire patterns disposed in different layers with one or more insulating layers interposed therebetween. The wire patterns disposed in different layers can be electrically connected through a contact hole penetrating the insulating layers.

A plurality of bank patterns 112 can be disposed on the insulating layer 204. At least one light-emitting element 100 can be disposed on each bank pattern 112.

The bank pattern 112 can be formed of an organic insulating material, such as, but not limited to, a photosensitive photo acryl or photosensitive polyimide. The bank pattern 112 can guide a position to which the light-emitting element 100 is to be attached during the transfer process of the light-emitting element 100. The bank pattern 112 can be omitted.

A solder pattern 118 can be disposed on the first electrode 102. The solder pattern 118 can be made of indium (In), tin (Sn), or an alloy thereof, but is not limited thereto.

The plurality of light-emitting elements 100 can be mounted on the respective solder patterns 118. One pixel can include three colors of light-emitting elements 100. For example, the light-emitting elements 100 can include a red light-emitting element, a green light-emitting element, or a blue light-emitting element. Two light-emitting elements can be mounted in each sub-pixel.

The first optical layer 136 can cover the plurality of light-emitting elements 100 and the plurality of bank patterns 112. Accordingly, the first optical layer 136 can cover between the plurality of light-emitting elements 100 and between the plurality of bank patterns 112. The first optical layer 136 can extend in the first direction X, and can be spaced apart in the second direction Y and separated between the pixel rows.

The first optical layer 136 can include an organic insulating material in which fine metal particles such as titanium dioxide particles are dispersed. Light emitted from the plurality of light-emitting elements 100 can be scattered by the fine metal particles dispersed in the first optical layer 136 and exited to the outside.

The second electrode 104 can be disposed on the plurality of light-emitting elements 100. The second electrode 104 can be commonly connected to the plurality of pixels PXL. The second electrode 104 can be a thin electrode through which light is transmitted. The second electrode 104 can be made of a transparent electrode material, e.g., indium tin oxide (ITO), but is not necessarily limited thereto.

The second electrode 104 can extend in the first direction (the X-axis direction) and can be spaced apart in the second direction (the Y-axis direction). On a plane, each of the plurality of second electrodes 104 can overlap the first optical layer 136 and can cover a plane outside of the first optical layer 136.

A second optical layer 127 can be an organic insulating material above the second electrode 104. The second optical layer 127 can include the same material as the first optical layer 136, (e.g., siloxane). However, the embodiment is not necessarily limited thereto, and the first optical layer 136 and the second optical layer 127 can be formed of the same material or different materials.

The second optical layer 127 can cover a portion above the second electrode 104. For example, the first optical layer 136 and the second optical layer 127 can function as a planarization layer. As a result, a pattern of a black matrix 128 on the second electrode 104 and the second optical layer 127 can be easily formed because there is no step in the plane on which the black matrix 128 is formed. However, the embodiment is not necessarily limited thereto, and the top surfaces of the second optical layer 127 and the second electrode 104 can have different heights.

The black matrix 128 can be an organic insulating material to which a black pigment is added. The second electrode 104 can be in contact with the contact electrode 106 below the black matrix 128. A transmission hole 154 can be formed between the patterns of the black matrix 128, through which light emitted from the light-emitting element 100 exits to the outside. The problem of mixing of light emitted from adjacent light-emitting elements 100 due to the first optical layer 136 can be improved by the black matrix 128.

A cover layer 156 can be an organic insulating material that covers the black matrix 128 and the second electrode 104. The contact electrode 106 can be electrically connected to the first connection wire RT1 disposed therebelow, and the first connection wire RT1 can be connected to the pixel driving circuit 201. Accordingly, a cathode voltage can be applied to the second electrode 104 through the contact electrode 106. The first electrode 102 can be electrically connected to the second connection wire RT2. This will be discussed later.

The contact electrode 106 and the signal wires TL1 to TL6 can be disposed on the same plane. The pixel driving circuit 201 can be disposed below the contact electrode 106 and the signal wires TL1 to TL6. When the pixel driving circuit 201 is a driver, a plurality of drivers can be disposed in the display panel.

A passivation layer 120 can expose the contact electrode 106 so that the contact electrode 106 and the second electrode 104 are electrically connected to each other. In addition, the passivation layer 120 can insulate the signal wires TL2 to TL5 from the second electrode 104.

Referring to FIG. 6, the extension portion 102a of the first electrode 102 can extend to one side 150 of the bank pattern 112 and be disposed on the insulating layer 204, and can be electrically connected to the connection wire RT2.

The first electrode 102, the extension portion 102a, the signal wire TL, and/or the connection wires RT1 and RT2 can include a single layer or a multi-layer of metals selected from titanium (Ti), molybdenum (Mo), and aluminum (Al).

The first layer ML1 and the third layer ML3 can include titanium (Ti) or molybdenum (Mo). The second layer ML2 can include aluminum (Al). The fourth layer ML4 can include a transparent conductive oxide layer, such as indium tin oxide (ITO) or indium zinc oxide (IZO), which has good adhesion to the solder pattern 118, corrosion resistance, and acid resistance.

The first layer ML1, the second layer ML2, the third layer ML3, and the fourth layer ML4 can be deposited sequentially and then patterned by performing a photolithography process and an etching process.

The passivation layer 120 can include an opening hole 120a disposed on the first electrode 102 and the signal wire TL and exposing the solder pattern 118.

The light-emitting element 10 can include a first conductivity type semiconductor layer 140, an active layer 142 disposed on the first conductivity type semiconductor layer 140, and a second conductivity type semiconductor layer 144 disposed on the active layer 142. A first driving electrode 146 can be disposed on the lower portion of the first conductivity type semiconductor layer 140 and a second driving electrode 148 can be disposed on the upper portion of the second conductivity type semiconductor layer 144.

The light-emitting element 100 can be formed on a silicon wafer by using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductivity type semiconductor layer 140 can be implemented with a compound semiconductor such as a group III-V or a group II-VI and can be doped with a first dopant. The first conductive type semiconductor layer 140 can be formed of one or more of the semiconductor materials having an empirical formula of Alₓ₁In_{y1}Ga_{(1-x1-y1)}N (0≤x1≤1, 0≤y1≤1, 0≤x1+y1≤1), InAlGaN, AlGaAs, GaP, GaAs, GaAsP, and AlGaInP, but is not limited thereto. When the first dopant is an n-type dopant such as Si, Ge, Sn, Se, or Te, the first conductivity type semiconductor layer 140 can be an n-type nitride semiconductor layer. However, when the first dopant is a p-type dopant, the first conductivity type semiconductor layer 140 can be a p-type nitride semiconductor layer.

The active layer 142 is a layer where electrons (or holes) injected through the first conductivity type semiconductor layer 140 and holes (or electrons) injected through the second conductivity type semiconductor layer 144 meet. The active layer 142 can transition to a low energy level as the electrons and the holes recombine, and can generate light having a corresponding wavelength.

The active layer 142 can have any one of a single well structure, a multi-well structure, a single quantum well structure, a multi-quantum well (MQW) structure, a quantum dot structure, or a quantum wire structure, but the structure of the active layer 142 is not limited thereto. The active layer 142 can generate light in a visible wavelength band. For example, the active layer 142 can output light in any one of blue, green, and red wavelength bands.

The second conductivity type semiconductor layer 144 can be disposed on the active layer 142. The second conductivity type semiconductor layer 144 can be implemented with a compound semiconductor such as a group III-V or a group II-VI, and the second conductivity type semiconductor layer 144 can be doped with a second dopant. The second conductive semiconductor layer 144 can be formed of a material selected from a semiconductor material having an empirical formula of Inₓ₂Al_{y2}Ga_{1-x2-y2}N (0≤x2≤1, 0≤y2≤1, 0≤x2+y2≤1) or AlInN, AlGaAs, GaP, GaAs, GaAsP, and AlGaInP. When the second dopant is a p-type dopant such as Mg, Zn, Ca, Sr, or Ba, the second conductivity type semiconductor layer 144 doped with the second dopant can be a p-type nitride semiconductor layer. When the second dopant is an n-type dopant, the second conductivity type semiconductor layer 144 can be an n-type nitride semiconductor layer.

Although the light-emitting element has been described as having a vertical structure with driving electrodes 146 and 148 disposed at the upper and lower portions of the light-emitting structure in the embodiments, the light-emitting element can also have a lateral structure or a flip chip structure in addition to the vertical structure.

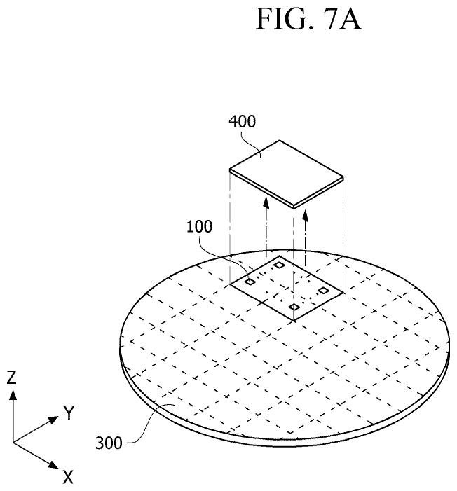

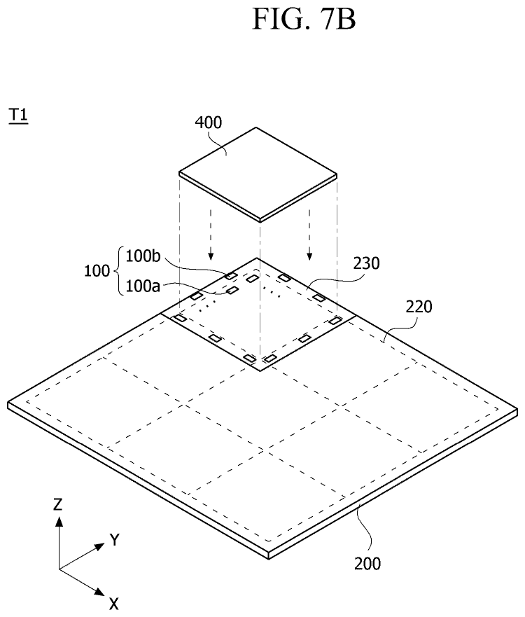

Hereinafter, a process of transferring a plurality of light-emitting elements constituting the display device to a substrate using a stamp for transferring the light-emitting elements according to one embodiment of the present disclosure will be described with reference to FIGS. 7A and 7B.

FIGS. 7A and 7B are perspective views illustrating a process of picking up and transferring the light-emitting elements using a light-emitting element transfer stamp according to one embodiment of the present disclosure.

Referring to FIGS. 7A and 7B, for transferring a plurality of light-emitting elements constituting the display device, there can be provided a growth substrate 300 having a plurality of light-emitting elements 100, a light-emitting element transfer stamp 400 for picking up and transferring the plurality of light-emitting elements 100, and a substrate 200 on which the plurality of light-emitting elements 100 are transferred to form a display panel.

The growth substrate 300 can be used as a substrate for growing the light-emitting elements 100, which are LED chips, and can be made of, but not limited to, silicon (Si), sapphire (Al₂O₃), silicon carbide (SiC), gallium arsenide (GaAs), gallium nitride (GaN), gallium phosphide (GaP), indium phosphide (InP), zinc oxide (ZnO), spinel (MgAl₂O₄), magnesium oxide (MgO), lithium metaaluminate (LiAlO₂), aluminum nitride (AlN), and lithiumgallate (LiGaO₂).

On the growth substrate 300, a plurality of micro light-emitting elements 100 can be grown.

Each light-emitting element 100 is a semiconductor device that emits light energy of various wavelengths by applying an electrical signal using the properties of a compound semiconductor. The light-emitting element 100 can be provided to have a thickness as small as a few microns.

The plurality of light-emitting elements 100 are arranged side-by-side in one direction on the growth substrate 300. The spacing between adjacent light-emitting elements 100 is set to have the smallest spacing possible in the process. For example, to reduce the manufacturing cost of the growth substrate 300, it is desirable to integrate as many light-emitting elements 100 as possible within a small growth substrate 300.

The light-emitting element transfer stamp 400 is used as a transfer means for transferring a plurality of light-emitting elements 100 from the growth substrate 300 to the substrate 200. The light-emitting element transfer stamp 400 selectively picks up the light-emitting elements 100 from the growth substrate 300. The light-emitting element transfer stamp 400 selectively picks up light-emitting elements 100 at predetermined locations and transfers them to respective corresponding pixels on the substrate 200.

The substrate 200 is a substrate constituting a display device and has a plurality of pixels arranged thereon. An area where the plurality of pixels are arranged can be defined as an active area. At least one light-emitting element 100 is finally allocated to each of the pixels. The signal wires and the electrodes for applying the driving signals to the light-emitting elements 100 can be arranged on the substrate 200. When implemented in an AM (active matrix) method, the substrate 20 for a panel can further include thin film transistors allocated for each pixel.

Referring to FIG. 7B, the light-emitting elements 100 transferred to adjacent pixels are arranged spaced apart at regular intervals. The spacing between adjacent light-emitting elements 100 of the light-emitting elements 100 transferred to the substrate 200 can be appropriately selected in consideration of display characteristics, element arrangement, and the like.

The substrate 200 can be provided to have a relatively larger size than the light-emitting element transfer stamp 400.

More specifically, the active area 220 of the substrate 200 can be provided to have a larger area than the area of the light-emitting element transfer stamp 400. In this case, in order to transfer the light-emitting elements 100 to all of the pixels arranged in the active area 220, as shown in FIGS. 7B, it is required to repeatedly perform multiple pickup/transfer operations in correspondence with the difference in area between the active area 220 and the light-emitting element transfer stamp 400.

In addition, the light-emitting element transfer processes, such as the first to fourth transfer processes T1 to T4 and the sixth to ninth transfer processes T6 to T9, using the light-emitting element transfer stamp 400, can be performed not only on the active area 220 but also on the dummy area 230 of the substrate 200, i.e., the display non-driving area.

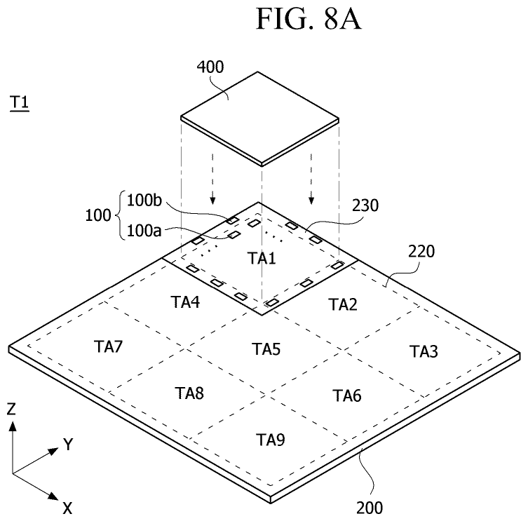

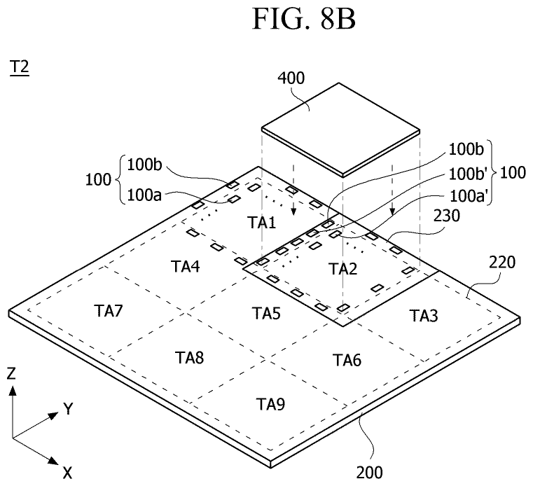

Hereinafter, a process of transferring a plurality of light-emitting elements onto a substrate using a light-emitting element transfer stamp according to one embodiment of the present disclosure will be described with reference to FIGS. 8A and 8B.

In this embodiment, the plurality of light-emitting elements 100 is described as including a plurality of first and second light-emitting elements 100a, 100a′, 100b, and 100b′.

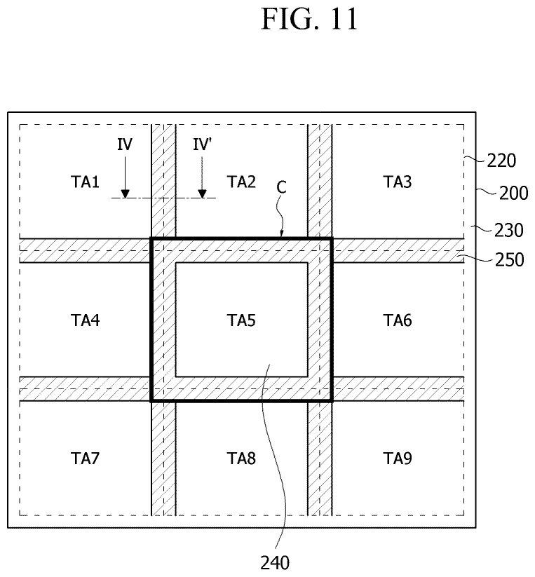

The plurality of first and second light-emitting elements 100a, 100a′, 100b, and 100b′ are of the same shape and are only intended to distinguish between light-emitting elements disposed in a non-overlapping transfer area 240 and an overlapping transfer area 250 of the substrate 200. For example, a plurality of first light-emitting elements 100a and 100a′ refers to the light-emitting elements that are transferred to the non-overlapping transfer area (see 240 in FIG. 11) of the substrate 200, and a plurality of second light-emitting elements 100b and 100b′ refers to the light-emitting elements that are transferred to the overlapping transfer area (see 250 in FIG. 11).

FIGS. 8A and 8B are perspective views illustrating first and second transfer processes using the light-emitting element transfer stamp according to one embodiment of the present disclosure.

Referring to FIG. 8A, a plurality of transfer areas, such as first to ninth transfer areas TA1 to TA9, can be defined on the substrate 200. While this embodiment describes an example where the first to ninth transfer areas TA1 to TA9 are defined on the substrate 200, it is also possible to describe an example where a certain number of transfer areas from first to sixteenth transfer areas are selected for definition. However, the embodiment is not necessarily limited thereto.

The embodiment of the present disclosure can be described by way of example in which first to ninth transfer processes T1 to T9 are performed corresponding to first to ninth transfer areas TA1 to TA9.

In other words, the transfer processes T1 to T9 of the light-emitting elements using the single stamp 400 are performed one to nine times, in correspondence with the first to ninth transfer areas TA1 to TA9 divided on the substrate 200.

In this case, when the transfer process of the light-emitting elements is performed nine times, the transfer process can be performed so that a portion of each of the first to ninth transfer areas TA1 to TA9 overlaps with each other during adjacent transfer processes.

In a state in which the stamp 400 on which the plurality of light-emitting elements 100 have been picked up is disposed in correspondence with the first transfer area TA1 of the substrate 200, the first transfer process T1 is performed to transfer the plurality of first and second light-emitting elements 100a and 100b to the first transfer area TA1 of the substrate 200.

In this case, the first transfer area TA1 on the substrate 200 includes an active area 220, which is a display driving area, and a dummy area 230, which is a display non-driving area.

Thus, among the plurality of first and second light-emitting elements 100a and 100b picked up on the stamp 400 when the first transfer process T1 is performed, a plurality of first light-emitting elements 100a can be transferred to the first transfer area TA1 within the active area 220, and a plurality of second light-emitting elements 100b can be transferred to the dummy area 230, which is the display non-driving area, and partial areas of the second and fourth transfer areas TA2 and TA4, i.e., areas corresponding to the overlapping transfer areas.

Referring to FIG. 8B, in a case in which the stamp 400 is disposed in correspondence with the second transfer area TA2 of the substrate 200, the second transfer process T2 is performed to transfer the plurality of first and second light-emitting elements 100a and 100b to the second transfer area TA2 of the substrate 200.

In this case, the second transfer area TA2 on the substrate 200 includes the active area 220, which is the display driving area, and the dummy area 230, which is the display non-driving area.

Thus, among the plurality of first and second light-emitting elements 100a′ and 100b′ picked up on the stamp 400 when the second transfer process T2 is performed, a plurality of first light-emitting elements 100a′ can be transferred to the second transfer area TA2 within the active area 220, and a plurality of second light-emitting elements 100b′ can be transferred to the dummy area 230, which is the display non-driving area, and partial areas of the first, third, and fifth transfer areas TA1, TA3, and TA5.

In other words, the second transfer process T2 is performed while overlapping a portion of the first transfer area TA1 to which the light-emitting elements were transferred during the first transfer process T1. In other words, during the second transfer process T2, a plurality of second light-emitting elements 100b′ can be transferred to the overlapping areas 250 of the first transfer area TA1 and the second transfer area TA2.

In this way, the plurality of first light-emitting elements 100a and 100a′ and second light-emitting elements 100b and 100b′ are transferred to the first to ninth transfer areas TA1 to TA9 of the substrate 200 by successively performing the first to ninth transfer processes T1 to T9.

During the first to ninth transfer processes T1 to T9, the overlapping transfer areas (250 in FIG. 11) are formed between the adjacent transfer areas, and the plurality of second light-emitting elements 100b and 100b′ are transferred and disposed in these overlapping transfer areas 250.

In addition, while performing the first to fourth transfer processes T1 to T4 and the sixth to ninth transfer processes T6 to T9, excluding the fifth transfer process T5, the plurality of second light-emitting elements 100b and 100b′ can also be transferred and disposed in the dummy area 230 of the substrate 200. The plurality of second light-emitting elements 100b and 100b′ transferred to the dummy area 230 are not used for display driving.

Additionally, during the first to ninth transfer processes T1 to T9 using the stamp 400, the plurality of second light-emitting elements 100b and 100b′ are transferred and disposed in the overlapping transfer areas 250, i.e., they are transferred and disposed without overlapping each other.

The stamp 400 can have an area that is a certain size, i.e., larger than each of the transfer areas TA1 to TA9 of the substrate 200, such as the overlapping transfer area 250.

In this way, since the first to ninth transfer processes T1 to T9 using the stamp 400 are performed so that the plurality of second light-emitting elements 100b and 100b′ are transferred and disposed in the overlapping transfer areas 250, the difference in process capability between the transfer processes using the stamp 400 can be offset.

Accordingly, the plurality of second light-emitting elements 100b and 100b′ can be transferred to the overlapping transfer areas 250 of the substrate 200 in an overlapping manner by the transfer processes using the stamp 400, thereby reducing the smear visibility caused by the difference in process capability for each stamp.

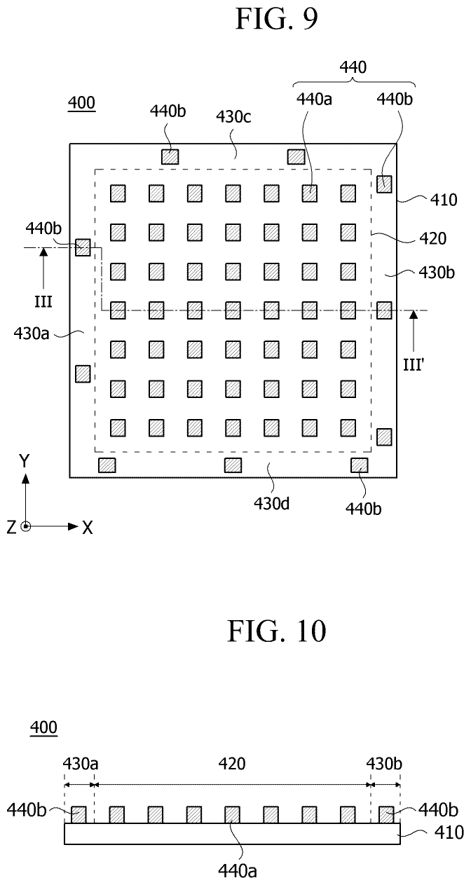

Hereinafter, a stamp structure for transferring the light-emitting elements according to one embodiment of the present disclosure will be described with reference to FIGS. 9 and 10.

FIG. 9 is a plan view illustrating a light-emitting element transfer stamp according to one embodiment of the present disclosure. FIG. 10 is a cross-sectional view taken along line III-III′ in FIG. 9.

Referring to FIG. 9, the light-emitting element transfer stamp 400 according to an embodiment of the present disclosure includes a non-overlapping stamp pattern area 420 defined in a center portion of an upper surface of a stamp substrate 410, and an overlapping stamp pattern area 430 adjoining the outer periphery of the non-overlapping stamp pattern area 420.

A plurality of first pickup transfer patterns 440a can be disposed at regular intervals in the first direction, which is the horizontal direction X, and the second direction, which is the vertical direction Y, in the non-overlapping stamp pattern area 420, and a plurality of second pickup transfer patterns 440b can be disposed in the overlapping stamp pattern area 430.

In a state where the plurality of light-emitting elements have been picked up from the growth substrate, the plurality of first pickup transfer patterns 440a for picking up and transferring the plurality of light-emitting elements can be disposed in correspondence with the non-overlapping transfer area (240 in FIG. 11) of the substrate (200 in FIG. 11) in order to transfer the plurality of light-emitting elements.

The plurality of second pickup transfer patterns 440b can be fewer than the plurality of first pickup transfer patterns 440a and can be disposed in correspondence with the overlapping transfer areas 250 of the substrate 200 in order to transfer the plurality of light-emitting elements.

The overlapping stamp pattern area 430 can include first and second overlapping stamp pattern areas 430a and 430b disposed relative to each other in the first direction, which is the horizontal direction (X), with the non-overlapping stamp pattern area 420 interposed therebetween, and third and fourth overlapping stamp pattern areas 430c and 430d disposed relative to each other in the second direction, which is the vertical direction (Y), with the non-overlapping stamp pattern area 420 interposed therebetween.

The plurality of second pickup transfer patterns 440b disposed in the first overlapping stamp pattern area 430a can be asymmetrical to, and can have different quantities or the same quantities as, the plurality of second pickup transfer patterns 440b disposed in the second overlapping stamp pattern area 430b on opposite side with the non-overlapping stamp pattern area 420 interposed therebetween.

The plurality of second pickup transfer patterns 440b disposed in the third overlapping stamp pattern area 430c can be asymmetrical to, and can have different quantities or the same quantity as, the plurality of second pickup transfer patterns 440b disposed in the fourth overlapping stamp pattern area 430d on opposite side with the non-overlapping stamp pattern area 420 interposed therebetween.

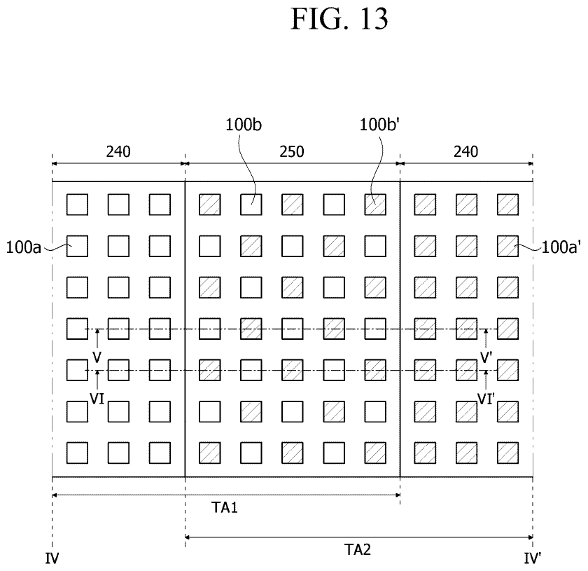

In other words, the plurality of second light-emitting elements (100b and 100b′ in FIG. 13) picked up on the plurality of second pickup transfer patterns 440b disposed in the first to fourth overlapping stamp pattern areas 430a to 430d can be transferred and disposed in the desired transfer locations without overlapping each other within the overlapping transfer areas 250 of the substrate during the transfer processes even when the first to ninth transfer processes by using the stamp 400 are performed.

Referring to FIG. 10, the light-emitting element transfer stamp 400 according to the present disclosure includes the stamp substrate 410 and the plurality of pickup transfer patterns 440 formed on the upper surface of the stamp substrate 410 at regular intervals.

The plurality of pickup transfer patterns 440 includes a plurality of first pickup transfer patterns 440a disposed on the non-overlapping stamp pattern areas 420 of the stamp substrate 410, and a plurality of second pickup transfer patterns 440b disposed in the overlapping stamp pattern area 430.

The quantity of the plurality of second pickup transfer patterns 440b disposed in the overlapping stamp pattern area 430 can be in the range of 1% to 10% of the total quantity of the plurality of first and second pickup transfer patterns 440a and 440b disposed on the stamp substrate 410.

The stamp substrate 410 can be used as a transfer means for transferring the light-emitting elements 100 from the growth substrate (300 in FIG. 7A) to the substrate (200 in FIG. 7B).

A quartz substrate, a sapphire substrate, or a silicon substrate can be used as the stamp substrate 210. However, the embodiment is not necessarily limited thereto.

The plurality of first and second pickup transfer patterns 440a and 440b serve to pick up the light-emitting elements using the material having surface adhesion properties, and the application of a flexible viscoelastic material allows for the pickup of light-emitting elements of various shapes, structures, and sizes without a complex spring structure as in conventional ones.

The plurality of first and second pickup transfer patterns 440a and 440b can have a rectangular, circular, or polygonal structure, but are not necessarily limited thereto.

The material of the plurality of first and second pickup transfer patterns 440a and 440b can be PDMS, PAC, urethane, acrylic, or epoxy. However, the embodiment is not necessarily limited thereto. The plurality of first and second pickup transfer patterns 440a and 440b can have any thickness.

The plurality of first and second pickup transfer patterns 440a and 440b can be undergone thermal expansion and deformation due to heat applied from the rear surface of the stamp substrate 410, causing their surface shapes to be deformed into a convex shape, protruding in the vertical direction of the stamp substrate 210, namely a rounded shape, which is advantageous for picking up the light-emitting elements.

A mechanism head for bonding the light-emitting element transfer stamp 400 is not limited to a vacuum head, an electrostatic head, or the like.

The light-emitting element transfer stamp 400 according to the present disclosure has predetermined adhesion (or adsorption) properties, so that it can selectively pick up the light-emitting elements 100 disposed at predetermined positions from the growth substrate (300 in FIG. 7A) by the adhesive force, and when the adhesive force is released and it can transfer the light-emitting elements 100 onto corresponding pixels in the substrate (200 in FIG. 7B).

The release of the adhesive force of the pickup transfer patterns 440 can be achieved using thermal or chemical properties. For example, a release layer can be provided between the stamp substrate 410 and the light-emitting element 100, and the adhesive force can be released by irradiating a laser to the release layer.

The following describes a process of transferring a plurality of light-emitting elements according to embodiments of the present disclosure.

While the embodiments of the present disclosure are described by way of example for the first and second transfer processes T1 and T2, the same can be applied to the third to ninth transfer processes T3 to T9 as to the first and second transfer processes.

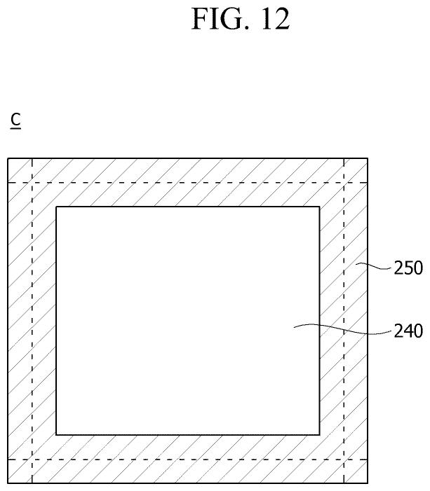

FIG. 11 is a plan view illustrating a substrate on which transfer areas are defined according to one embodiment of the present disclosure. FIG. 12 is an enlarged view of an area C in FIG. 11.

Referring to FIG. 11, the substrate 200 for a panel on which the light-emitting elements are transferred through the light-emitting element transfer stamp 400 according to an embodiment of the present disclosure can include the active area 220, which is the display driving area, and the dummy area 230, which is the display non-driving area, on the outer periphery of the active area 220.

The active area 220 can include the first to ninth non-overlapping transfer areas 240, and the overlapping transfer zones 250 disposed outside of the first to ninth non-overlapping transfer zones 240.

In the dummy area 230, the plurality of second light-emitting elements 100b picked up by the plurality of second light-emitting element transfer patterns 440b disposed in the first to fourth overlapping pickup transfer areas 430a to 430d of the stamp 400 during the first to fourth transfer processes and the sixth to ninth transfer processes, excluding the fifth transfer process, can be transferred and disposed.

Referring to FIGS. 11 and 12, the non-overlapping transfer area 240 can be formed in a central area of the fifth transfer area TA5 by means of the fifth transfer process T5 on the substrate 200, and the overlapping transfer areas 250 can be formed adjacent to the outer periphery of the non-overlapping transfer area 240.

For example, the overlapping transfer area 250 defined during the fifth transfer process T5 and each of the overlapping transfer areas 250 when the second, fourth, sixth, and eighth transfer processes T2, T4, T6, and T8 are performed can have one surface overlapping with each other.

In addition, the overlapping transfer area 250 defined during the fifth transfer process T5 and each of the overlapping transfer areas 250 when the first, third, seventh, and ninth transfer processes T1, T3, T7, and T9 are performed can have one corner portion overlapping with each other.

In other words, the overlapping transfer area 250 can be formed between the transfer processes that are adjacent to each other in the first to ninth transfer processes T1 to T9. By forming the overlapping transfer areas 250 across a plurality of transfer areas TA1 to TA9 defined on the substrate 200 during the first to ninth transfer processes using the stamp 400, it is possible to offset the difference in process capability between the transfer processes by means of the stamp 400 in the overlapping transfer area 250, thereby improving the visibility of the stamp smear.

In order to improve the visibility of the stamp smear by offsetting the difference in process capability between the transfer processes in the overlapping transfer area 250, it can be desirable to increase the area of the overlapping transfer area 250.

However, when the area of the overlapping transfer area 250 is increased, the area of the dummy area 230 is also increased, resulting in an increase in the quantity of light-emitting elements 200 disposed in the dummy area 230.

While this can improve the visibility of the stamp smear in the overlapping transfer area 250, it can reduce the number of the light-emitting elements 100 disposed in the substrate 200, which can result in a lower profitability.

Thus, in order to limit the quantity of light-emitting elements 100 to be disposed in the dummy area 230 while appropriately maintaining the area of the overlapping transfer area 250, the quantity of light-emitting elements 100 transferred and disposed in the overlapping transfer area 250 formed on the substrate 200 can be set in the range of 1 to 10% of the quantity of light-emitting elements 100 transferred and disposed in the entire substrate 200.

Alternatively, the quantity of light-emitting elements 100 that are transferred and disposed in the overlapping transfer area 250 of the substrate 200 can be equal to or less than the quantity of light-emitting elements 100 that are transferred to the dummy area 230 of the substrate 200.

In particular, as the area of the dummy area 230 increases, the overlapping transfer area 250 also increases, so it is necessary to effectively adjust the area of the dummy area 230 to improve the visibility of the stamp smear by means of the overlapping transfer area 250 while keeping the area of the dummy area 230 as small as possible.

Therefore, a plurality of second light-emitting elements 100b can be transferred and disposed in the overlapping transfer area 250 by performing the first transfer process T1 using the stamp 400, and then a plurality of second light-emitting elements 100b′ can be transferred and disposed in the overlapping transfer area 250 by performing the second transfer process T2 using the stamp 400 as used in the first transfer process T1.

This can offset the difference in degree of light emission efficiency in the overlapping transfer area 250, resulting in a reduction in smear visibility.

FIG. 13 is a cross sectional view taken along line IV-IV in FIG. 11.

Referring to FIG. 13, a plurality of first light-emitting elements 100a and 100a′ and a plurality of second light-emitting elements 100b and 100b′ are transferred and disposed on the substrate 200 by performing the first and second transfer processes T1 and T2 using the stamp for transferring light-emitting elements according to an embodiment of the present disclosure.

Among the plurality of first and second light-emitting elements 100a and 100b, the first light-emitting elements 100a are light-emitting elements that are transferred and disposed in the non-overlapping transfer area 240 defined in the first transfer area TA1 during the first transfer process T1, and the plurality of second light-emitting elements 100b are light-emitting elements that are transferred and disposed in the overlapping transfer area 250 of the first transfer area TA1 during the first transfer process T1.

In addition, among the plurality of first and second light-emitting elements 100a′ and 100b′, the first light-emitting elements 100a′ are light-emitting elements that are transferred and disposed in the non-overlapping transfer area 240 defined in the second transfer area TA2 during the second transfer process T2, and the plurality of second light-emitting elements 100b′ are light-emitting elements that are transferred and disposed in the overlapping transfer area 250 of the second transfer area TA2 during the second transfer process.

In this embodiment, the plurality of first and second light-emitting elements 100a and 100b that are transferred and disposed in the first transfer process T1 and the plurality of first and second light-emitting elements 100a′ and 100b′ that are transferred and disposed in the second transfer process T2 are light-emitting elements of the same type. The definition is only made to distinguish the light-emitting elements that are transferred and disposed during the first transfer process T1 and the second transfer process T2.

And, in this embodiment, the light-emitting elements transferred and disposed during the first to ninth transfer processes T1 to T9 all have the same area and size, and the same single stamp 400 is used to pick up the light-emitting elements disposed on the growth substrate 300 and transfer them to the substrate 200.

Referring to FIG. 13, a plurality of first and second light-emitting elements 100a and 100b are transferred and disposed on a first transfer area TA1 of the substrate 200 through the first transfer process T1 using the stamp 400.

The plurality of first light-emitting elements 100a are transferred and disposed within the non-overlapping transfer area 240 of the substrate 200.

The plurality of first light-emitting elements 100a are disposed at regular intervals in the non-overlapping transfer area 240 in the first direction, which is the horizontal direction, and the second direction, which is the vertical direction.

The plurality of second light-emitting elements 100b are transferred and disposed within the overlapping transfer area 250 of the substrate 200.

The plurality of second light-emitting elements 100b are disposed at regular intervals within the overlapping transfer area 250 of the substrate 2000, and are alternately disposed in the first direction, which is the horizontal direction, and the second direction, which is the vertical direction.

Continuing to refer to FIG. 13, a plurality of first and second light-emitting elements 100a′ and 100b′ are transferred and disposed on the second transfer area TA2 of the substrate 200 through the first transfer process T2 using the stamp 400.

The plurality of first light-emitting elements 100a′ are transferred and disposed within the non-overlapping transfer area 240 of the second transfer area TA2 of the substrate 200.

The plurality of first light-emitting elements 100a′ are disposed at regular intervals in the non-overlapping transfer area 240 in the first direction, which is the horizontal direction, and the second direction, which is the vertical direction.

The plurality of second light-emitting elements 100b′ are transferred and disposed within the overlapping transfer area 250 of the second transfer area TA2 of the substrate 200.

Here, the overlapping transfer area 250 refers to a shared area that is transferred by overlapping each other when the first transfer process T1 and the second transfer process T2 are performed.

The plurality of second light-emitting elements 100b′ are disposed at regular intervals within the overlapping transfer area 250 of the substrate 200, and are alternately disposed in the first direction, which is the horizontal direction, and the second direction, which is the vertical direction.

In this case, the plurality of second light-emitting elements 100b that are transferred during the first transfer process T1 and the plurality of second light-emitting elements 100b′ that are transferred during the second transfer process T2 are disposed at regular intervals within the overlapping transfer area 250 of the substrate 200.

In addition, the plurality of second light-emitting elements 100b and 100b′ that are transferred to the overlapping transfer area 250 during the first and second transfer processes T1 and T2 are disposed at predetermined positions without overlapping each other.

Additionally, the plurality of second light-emitting elements 100b and 100b′ can be disposed in the overlapping transfer region 250 at regular intervals in the first direction, which is the horizontal direction, and the second direction, which is the vertical direction.

Meanwhile, the plurality of second light-emitting elements 100b and 100b′ can be disposed in the overlapping transfer area 250 overlapping each other during the third to ninth transfer processes T3 to T9 besides during the first and second transfer processes T1 and T2, at regular intervals in the first direction, which is the horizontal direction and the second direction, which is the vertical direction.

As described above, during the first to ninth transfer processes, the plurality of second light-emitting devices 100b and 100b′ can be disposed without overlapping each other in the overlapping transcription area 250 defined in each of the transfer areas.

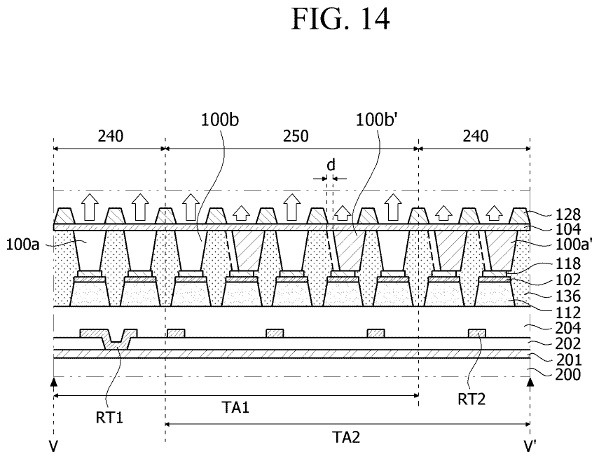

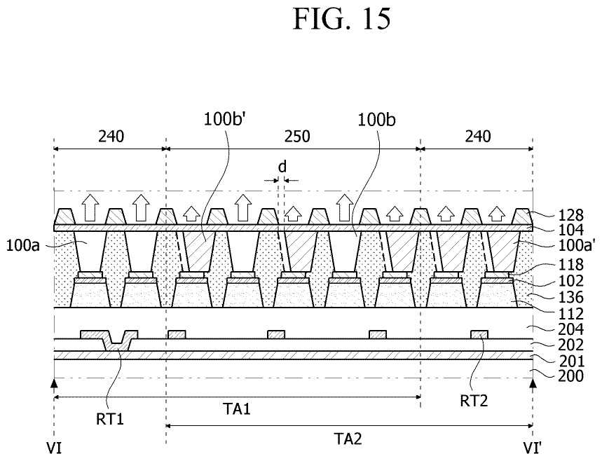

FIG. 14 is a cross-sectional view taken along line V-V′ in FIG. 13. FIG. 15 is a cross-sectional view taken along line VI-VI′ in FIG. 13.

Referring to FIGS. 14 and 15, in the display device according to an embodiment of the present disclosure, the bank pattern 112 is disposed on the substrate 200, and a plurality of first electrodes 102 is disposed on the bank pattern 112.

A plurality of light-emitting elements 100 are disposed on the plurality of first electrodes 102, and the first optical layer 136 is disposed between the plurality of light-emitting elements 100.

The plurality of light-emitting elements 100 can include a plurality of first light-emitting elements 100a and 100a′ and a plurality of second light-emitting elements 100b and 100b′. The plurality of first light-emitting elements 100a and 100a′ and the plurality of second light-emitting elements 100b and 100b′ can have the same structure, area, and size.

The plurality of first light-emitting elements 100a and 100a′ and the plurality of second light-emitting elements 100b and 100b′ defined in the embodiments of the present disclosure are defined to distinguish light-emitting elements that are transferred and disposed on the non-overlapping transfer area 240 and the overlapping transfer area 250 through the first to ninth transfer processes T1 to T9.

The second electrode 104 is disposed on the plurality of light-emitting elements 100 and the first optical layer 136.

Then, the black matrix 128 is disposed on the second electrode 104 to overlap an area between the plurality of light-emitting elements 100.

Light emitted from the plurality of light-emitting elements 100 is emitted from the area between the black matrices 128.

During the first transfer process T1, the plurality of first and second light-emitting elements 100a and 100b are transferred and disposed in the non-overlapping transfer area 240 and the overlapping transfer region 250 defined in the first transfer area TA1 of the substrate 200, respectively.

The plurality of first light-emitting elements 100a and 100a′ transferred and disposed in the non-overlapping transfer areas 240 in the first direction, which is the horizontal direction, are disposed to be symmetrical with respect to the plurality of first light-emitting elements 100a and 100a′ disposed upward and downward in the second direction, which is the vertical direction.

The plurality of second light-emitting elements 100b that are transferred and disposed in the overlapping transfer area 250 during the first transfer process T1 are alternately disposed in the first direction, which is the horizontal direction, and the second direction, which is the vertical direction.

In addition, the plurality of second light-emitting elements 100b′ that are transferred and disposed in the overlapping transfer area 250 during the second transfer process T2 are alternately disposed in the first direction, which is the horizontal direction, and the second direction, which is the vertical direction.

In other words, within the overlapping transfer area 250, the plurality of second light-emitting elements 100b and 100b′ are alternately disposed at regular intervals without overlapping each other.

For example, when the first transfer process T1 is performed, within the overlapping transfer region 250, three second light-emitting elements 100b are transferred and disposed at regular intervals in a first row in the first direction, and two second light-emitting elements 100b are transferred and disposed, asymmetrically with the three second light-emitting elements 100b in the first row, in a second row, which is a next row of the first row, so as not to overlap each other.

Accordingly, the plurality of second light-emitting elements 100b disposed within the overlapping transfer area 250 are alternately disposed for each row.

On the other hand, in the second transfer process T2, two second light-emitting elements 100b′ are transferred and disposed at regular intervals in the first row in the first direction within the overlapping transfer area 250, and three second light-emitting elements 100b′ are transferred and disposed, asymmetrically with the two second light-emitting elements 100b′ in the first row, in a second row, which is a next row of the first row, so as not to overlap each other.

Accordingly, the plurality of second light-emitting elements 100b′ disposed within the overlapping transfer area 250 are alternately disposed in each of the upper and lower rows.

In addition, during the second transfer process T2, the plurality of second light-emitting elements 100b′ to be disposed within the overlapping transfer area 250 are disposed between the plurality of second light-emitting elements 100b transferred and disposed during the first transfer process T1.

Accordingly, the plurality of second light-emitting elements 100b′ to be disposed within the overlapping transfer area 250 during the second transfer process T2 are disposed for each row and column so as to correspond to the plurality of second light-emitting elements 100b disposed within the overlapping transfer area 250 during the first transfer process T1.

Continuing refer to FIGS. 14 and 15, the plurality of first light-emitting elements 100a and 100a′ and the plurality of second light-emitting elements 100b and 100b′ are disposed on the solder pattern 118 on the first electrode 102 located in the non-overlapping transfer areas 240 and the overlapping transfer areas 250 of the substrate 200 to electrically connect to the first electrode 102.

In addition, during the first and second transfer processes T1 and T2, the plurality of first and second light-emitting elements 100a and 100b′ are transferred and disposed in the non-overlapping transfer area 240 and the overlapping transfer area 250 defined in the second transfer area TA1 of the substrate 200, respectively.

The plurality of first and second light-emitting elements 100a′ and 100b′ are disposed on the solder patterns 118 disposed on the plurality of first electrodes 102 located in the non-overlapping transfer area 240 and the overlapping transfer area 250 of the substrate 200 and electrically connected to the first electrodes 102.

During the second transfer process T2, unlike the first transfer process T1, the plurality of first and second light-emitting elements 100a′ and 100b′ can be transferred and disposed in a state in which they are slightly shifted by the separation distance d instead of being exactly disposed on the solder patterns 118 on the first electrodes 102.

This means that the transfer processes performed multiple times using the stamp may not accurately transfer the light-emitting elements due to a difference in the transfer process capability of the stamp in the process of transferring the light-emitting elements 100 onto the substrate 200 by transferring the stamp for picking up and transferring the light-emitting element each time, but can transfer the light-emitting elements to be disposed in a state in which a portion of each of the light-emitting elements on the solder patterns 118 on the first electrodes 102 is slightly shifted by a separation distance d due to a slight shift during operation of a pick-up and transfer device.

As a result, within the overlapping transfer area 250, some of the plurality of second light-emitting elements 100b′ can be disposed to partially overlap the black matrix 128 disposed to overlap between the light-emitting elements.

Therefore, compared to the first transfer process, a portion of the light emitted from the plurality of second light-emitting elements 100b′ within the overlapping transfer area 250 can be blocked by the black matrix 128, resulting in a reduction in light emission efficiency.

However, the plurality of second light-emitting elements 100b, which are transferred and disposed in the overlapping transfer region 250 during the first transfer process T1, are disposed on the solder pattern 118 on the first electrode 102 without shifting, and thus do not overlap the black matrix 128 disposed to overlap between the plurality of second light-emitting elements 100.

Accordingly, the light emission efficiency from the plurality of second light-emitting elements 100b that are transferred and disposed in the overlapping transfer area 250 in the first transfer process T1 is not reduced, and the same light emission efficiency as the light emission efficiency from the plurality of first light-emitting elements 100a that are disposed in the non-overlapping transfer area 240 can be maintained.

As a result, due to the difference in transfer performance during the first transfer process T1 and the second transfer process T2, a plurality of second light-emitting elements 100b having excellent light emission efficiency and a plurality of second light-emitting elements 100b′ having reduced light emission efficiency can be transferred and cross-disposed in the overlapping transfer area 250. Accordingly, the difference in degree of light emission efficiency in the overlapping transfer area 250 can be offset, and thus a smear visibility reduction effect can be achieved at the boundary between the transfer areas.

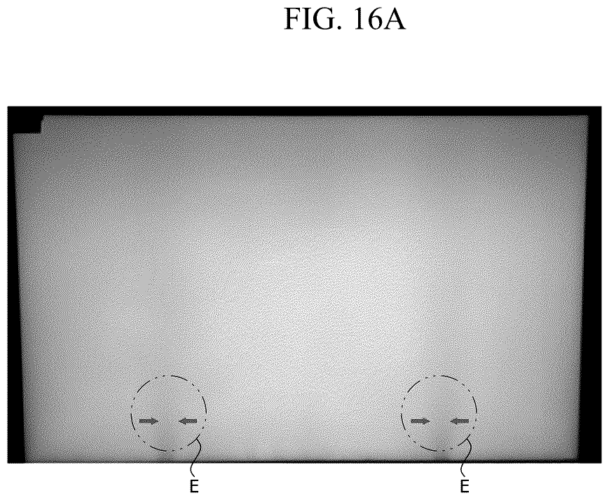

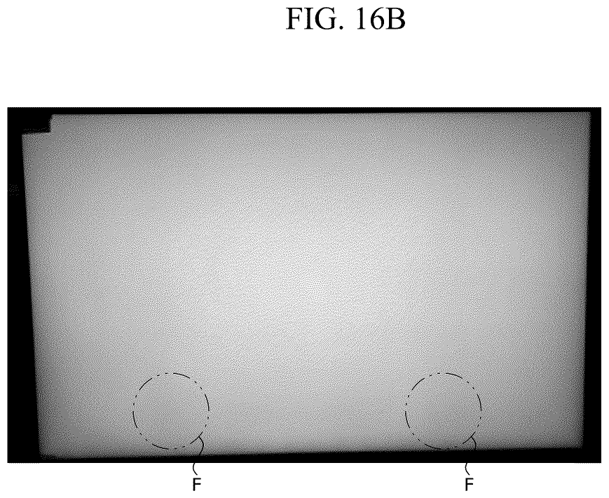

FIGS. 16A and 16B are diagrams illustrating whether or not stamp smears are visible when the overlapping transfer area is employed and not employed during a process of transferring a plurality of light-emitting elements using a stamp according to one embodiment of the present disclosure.

Referring to FIG. 16A, a plurality of light-emitting elements are transferred and disposed in the substrate by performing a plurality of transfer processes on the substrate using the stamp. In this case, the plurality of light-emitting elements are transferred and disposed in the substrate by performing the plurality of transfer processes without the overlapping transfer area during the transfer processes.

At this time, as shown in an area E of FIG. 16A, it can be confirmed that a stamped smear is clearly visible at a boundary between the first and second transfer areas during adjacent transfer processes, such as during the first transfer process T1 and the second transfer process T2.

However, referring to FIG. 16B, which demonstrate an embodiment of the present disclosure, a case in which a plurality of light-emitting elements are transferred and disposed in the substrate by performing a plurality of transfer processes using the stamp is illustrated. This case indicates that a plurality of light-emitting elements are transferred and disposed in the overlapping transfer area during the plurality of transfer processes.

In this case, as shown in an area F in FIG. 16B, it can be confirmed that visibility due to the stamping smear is improved at the boundary between the first and second transfer areas by forming the overlapping transfer area (250 in FIG. 13) between the first and second transfer areas during adjacent transfer processes such as during the first transfer process (T1 in FIG. 13) and the second transfer process (T2 of FIG. 13).

The display device according to the embodiment of the present disclosure can be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a laptop computer, a monitor, a camera, a camcorder, a home appliance, etc. In addition, the display device according to one or more embodiments of the present disclosure can be applied to an organic light emitting lighting device or an inorganic light emitting lighting device.

The stamp for transferring light-emitting elements according to various embodiments of the present disclosure can be described as follows.

A display device according to one embodiment of the present disclosure can comprise a stamp substrate; a non-overlapping stamp pattern area defined on the stamp substrate, and an overlapping stamp pattern area adjoining an outer periphery of the non-overlapping stamp pattern area; a plurality of first pickup transfer patterns disposed in the non-overlapping stamp pattern area; and a plurality of second pickup transfer patterns disposed in different lines in the overlapping stamp pattern areas with the non-overlapping stamp pattern area interposed therebetween.

According to one embodiment of the present disclosure, the overlapping stamp pattern area can include first and second overlapping stamp pattern areas and third and fourth overlapping stamp pattern areas, which are disposed to face each other with the non-overlapping stamp pattern area interposed therebetween.

According to one embodiment of the present disclosure, the plurality of second pickup transfer patterns disposed in the first and second overlapping stamp pattern areas disposed to face each other can be located on different lines, and the plurality of second pickup transfer patterns disposed in the third and fourth overlapping stamp pattern areas disposed to face each other are located on different lines.

According to one embodiment of the present disclosure, the quantities of the plurality of second pickup transfer patterns that can be disposed in the overlapping stamp pattern areas are different or the same.

According to one embodiment of the present disclosure, the quantity of the plurality of second pickup transfer patterns disposed in the overlapping stamp pattern areas can be in the range of 1 to 10% of the total quantity of the plurality of first and second pickup transfer patterns disposed in the entirety of the overlapping stamp pattern areas and the non-overlapping stamp pattern area.

A method for transferring light-emitting elements using a stamp according to one embodiment of the present disclosure can comprise preparing a substrate having a plurality of transfer areas divided into non-overlapping and overlapping transfer areas; preparing a stamp, the stamp including a plurality of first pickup transfer patterns configured to transfer a plurality of first light-emitting elements to the non-overlapping transfer areas of the substrate, and a plurality of second pickup transfer patterns configured to transfer a plurality of second light-emitting elements to the overlapping transfer areas of the substrate; and transferring the plurality of first light-emitting elements picked up onto the plurality of first pickup transfer patterns to the non-overlapping transfer areas of the substrate and transferring the plurality of second light-emitting elements picked up onto the plurality of second pickup transfer patterns to the overlapping transfer areas, by performing a plurality of transfer processes using the stamp.

According to one embodiment of the present disclosure, the plurality of second light-emitting elements are transferred to the overlapping transfer area of each of the plurality of transfer areas by performing the transfer process at least twice.

According to one embodiment of the present disclosure, among the plurality of second light-emitting elements transferred to the overlapping transfer area of each of the plurality of transfer areas, a plurality of second light-emitting elements transferred during a first transfer process and a plurality of second light-emitting elements transferred during a second transfer process can be transferred to the overlapping transfer areas without overlapping each other.

According to one embodiment of the present disclosure, the plurality of first light-emitting elements can be transferred to the non-overlapping transfer area of each of the plurality of transfer areas by a single transfer process.

According to one embodiment of the present disclosure, the overlapping transfer areas of the substrate can include first and second overlapping transfer areas disposed to face each other in a first direction, which is a horizontal direction, with the non-overlapping transfer area interposed therebetween, and third and fourth overlapping transfer areas disposed to face each other in a second direction, which is a vertical direction, with the non-overlapping transfer area interposed therebetween.

According to one embodiment of the present disclosure, the plurality of second light-emitting elements disposed in the first and second overlapping transfer areas can be located on different lines in the first and second directions, and the plurality of second light-emitting elements disposed in the third and fourth overlapping transfer areas are located on different lines in the first and second directions.

According to one embodiment of the present disclosure, the quantities of the plurality of second light-emitting elements that can be disposed in the first and second overlapping transfer areas are different or the same, and the quantities of the plurality of second light-emitting elements that are disposed in the third and fourth overlapping transfer areas are different or the same.

According to one embodiment of the present disclosure, the quantity of the plurality of second light-emitting elements that can be disposed in the overlapping transfer areas is in the range of 1 to 10% of the total quantity of the plurality of first and second light-emitting elements transferred in the non-overlapping transfer areas and the overlapping transfer areas.

According to one embodiment of the present disclosure, the transfer areas adjoining each other among a plurality of transfer areas of the substrate share the overlapping transfer areas when a plurality of transfer processes is performed.

According to one embodiment of the present disclosure, the quantity of the plurality of second light-emitting elements transferred to the overlapping transfer areas can be less than or equal to the quantity of the plurality of second light-emitting elements transferred to a dummy area of the substrate.

A display device according to one embodiment of the present disclosure can comprise a substrate having a plurality of transfer areas; non-overlapping and overlapping transfer areas defined in each of the plurality of transfer areas; a plurality of bank patterns disposed in the non-overlapping transfer areas and the overlapping transfer areas of the substrate; a plurality of first electrodes disposed on the plurality of bank patterns; a plurality of light-emitting elements disposed on the plurality of first electrodes; and a second electrode disposed on the plurality of light-emitting elements, wherein the light-emitting elements disposed in the overlapping transfer areas include light-emitting elements that overlap with the bank pattern to each other on the first electrode and light-emitting elements having a portion which does not overlap with the bank pattern on the first electrode.

According to one embodiment of the present disclosure, the quantity of the plurality of light-emitting elements disposed in the overlapping transfer areas is in the range of 1 to 10% of the total quantity of the plurality of light-emitting elements transferred in the non-overlapping transfer areas and the overlapping transfer areas.

According to one embodiment of the present disclosure, the light-emitting elements that overlap with each other on the first electrode, and light-emitting elements whose portion does not overlap with each other on the first electrode are included in each of the overlapping transfer areas of the transfer areas.

According to one embodiment of the present disclosure, the quantity of the plurality of light-emitting elements disposed in the overlapping transfer areas is less than or equal to the quantity of the plurality of light-emitting elements transferred to a dummy area of the substrate.

According to one embodiment of the present disclosure, the display device further includes a black matrix disposed on the second electrode to overlap an area between the plurality of light-emitting elements, and the light-emitting elements having a portion which does not overlap with the bank pattern are disposed to partially overlap the black matrix.

The effects of the present disclosure are not limited to the above-described effects, and other effects that are not mentioned will be able to be clearly understood by those skilled in the art from the above detailed description.

Although embodiments of the present disclosure have been described in more detail with reference to the accompanying drawings, the present disclosure is not necessarily limited to the embodiments, and various modifications can be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A stamp for transferring light-emitting elements, the stamp comprising:
a stamp substrate;
a non-overlapping stamp pattern area defined on the stamp substrate, and an overlapping stamp pattern area adjoining an outer periphery of the non-overlapping stamp pattern area;
a plurality of first pickup transfer patterns disposed in the non-overlapping stamp pattern area; and
a plurality of second pickup transfer patterns disposed in different lines in the overlapping stamp pattern area with the non-overlapping stamp pattern area interposed therebetween.

2. The stamp of claim 1, wherein the overlapping stamp pattern area includes first and second overlapping stamp pattern areas and third and fourth overlapping stamp pattern areas, which are disposed to face each other with the non-overlapping stamp pattern area interposed therebetween.

3. The stamp of claim 2, wherein the plurality of second pickup transfer patterns disposed in the first and second overlapping stamp pattern areas disposed to face each other are located on different lines, and
wherein the plurality of second pickup transfer patterns disposed in the third and fourth overlapping stamp pattern areas disposed to face each other are located on different lines.

4. The stamp of claim 1, wherein quantities of the plurality of second pickup transfer patterns that are disposed in the overlapping stamp pattern area are different or same.

5. The stamp of claim 1, wherein a quantity of the plurality of second pickup transfer patterns disposed in the overlapping stamp pattern area is in a range of 1 to 10% of a total quantity of the plurality of first and second pickup transfer patterns disposed in the entirety of the overlapping stamp pattern area and the non-overlapping stamp pattern area.

6. A method for transferring light-emitting elements using a stamp, the method comprising:
preparing a substrate having a plurality of transfer areas divided into non-overlapping transfer areas and overlapping transfer areas;
preparing a stamp including a plurality of first pickup transfer patterns and a plurality of second pickup transfer patterns, the plurality of first pickup transfer patterns configured to transfer a plurality of first light-emitting elements to the non-overlapping transfer areas of the substrate, and the plurality of second pickup transfer patterns configured to transfer a plurality of second light-emitting elements to the overlapping transfer areas of the substrate; and
transferring the plurality of first light-emitting elements picked up onto the plurality of first pickup transfer patterns to the non-overlapping transfer areas of the substrate and transferring the plurality of second light-emitting elements picked up onto the plurality of second pickup transfer patterns to the overlapping transfer areas, by performing a plurality of transfer processes using the stamp.

7. The method of claim 6, wherein the plurality of second light-emitting elements are transferred to the overlapping transfer area of each of the plurality of transfer areas by performing the transfer process at least twice.

8. The method of claim 7, wherein, among the plurality of second light-emitting elements transferred to the overlapping transfer area of each of the plurality of transfer areas, a plurality of second light-emitting elements transferred during a first transfer process and a plurality of second light-emitting elements transferred during a second transfer process are transferred to the overlapping transfer areas without overlapping each other.

9. The method of claim 6, wherein the plurality of first light-emitting elements are transferred to the non-overlapping transfer area of each of the plurality of transfer areas by a single transfer process.

10. The method of claim 8, wherein the overlapping transfer areas of the substrate include:
first and second overlapping transfer areas disposed to face each other in a first direction, with the non-overlapping transfer area interposed therebetween; and
third and fourth overlapping transfer areas disposed to face each other in a second direction crossing the first direction, with the non-overlapping transfer area interposed therebetween.

11. The method of claim 10, wherein the plurality of second light-emitting elements disposed in the first and second overlapping transfer areas are located on different lines in the first and second directions, and
wherein the plurality of second light-emitting elements disposed in the third and fourth overlapping transfer areas are located on different lines in the first and second directions.

12. The method of claim 11, wherein quantities of the plurality of second light-emitting elements that are disposed in the first and second overlapping transfer areas are different or same, and
wherein quantities of the plurality of second light-emitting elements that are disposed in the third and fourth overlapping transfer areas are different or same.

13. The method of claim 6, wherein a quantity of the plurality of second light-emitting elements that are disposed in the overlapping transfer areas is in a range of 1 to 10% of a total quantity of the plurality of first and second light-emitting elements transferred in the non-overlapping transfer areas and the overlapping transfer areas.

14. The method of claim 6, wherein the transfer areas adjoining each other among a plurality of transfer areas of the substrate share the overlapping transfer areas when a plurality of transfer processes are performed.

15. The method of claim 6, wherein a quantity of the plurality of second light-emitting elements transferred to the overlapping transfer areas is less than or equal to a quantity of the plurality of second light-emitting elements transferred to a dummy area of the substrate.

16. A display device comprising:
a substrate having a plurality of transfer areas;
non-overlapping transfer areas and overlapping transfer areas defined in each of the plurality of transfer areas;
a plurality of bank patterns disposed in the non-overlapping transfer areas and the overlapping transfer areas of the substrate;
a plurality of first electrodes disposed on the plurality of bank patterns;
a plurality of light-emitting elements disposed on the plurality of first electrodes; and
a second electrode disposed on the plurality of light-emitting elements,
wherein the plurality of light-emitting elements disposed in the overlapping transfer areas include light-emitting elements that overlap with one of the plurality of bank patterns on one of the plurality of first electrodes, and light-emitting elements having a portion which does not overlap with the one of the plurality of bank patterns on the one of the plurality of first electrodes.

17. The display device of claim 16, wherein a quantity of the plurality of light-emitting elements disposed in the overlapping transfer areas is in a range of 1 to 10% of a total quantity of the plurality of light-emitting elements transferred in the non-overlapping transfer areas and the overlapping transfer areas.

18. The display device of claim 16, wherein the light-emitting elements that overlap with the one of the plurality of bank patterns, and the light-emitting elements having the portion which does not overlap with the one of the plurality of bank patterns are included in each of the overlapping transfer areas of the plurality of transfer areas.

19. The display device of claim 16, wherein a quantity of the plurality of light-emitting elements disposed in the overlapping transfer areas is less than or equal to a quantity of the plurality of light-emitting elements transferred to a dummy area of the substrate.

20. The display device of claim 16, further comprising a black matrix disposed on the second electrode to overlap an area between the plurality of light-emitting elements,
wherein the light-emitting elements having a portion which does not overlap with the plurality of bank pattern are disposed to partially overlap with the black matrix.
